(19) United States
(12) Patent Application Publication
(10) Pub. No.: US 2011/0130009 A1
(43) Pub. Date: Jun. 2, 2011

(54) METHOD AND APPARATUS FOR SURFACE TREATMENT USING A MIXTURE OF ACID AND OXIDIZING GAS

(75) Inventors: Robert KUMNIG, LEDENITZEN (AT); Reinhard SELLMER, Rottenburg (DE)

(73) Assignee: LAM RESEARCH AG, VILLACH (AT)

(21) Appl. No.: 12/627,953

(22) Filed: Nov. 30, 2009

(51) Int. Cl. H01L 21/306

(52) U.S. Cl. 438/745; 156/345.21; 257/E21.219

(57) ABSTRACT

Improved removal of ion-implanted photoresist in a single wafer front-end wet processing station is achieved by combining gaseous ozone and heated sulfuric acid such that a gas/liquid dispersion or foam of ozone in sulfuric acid is applied in a layer to the wafer surface to be treated.

### BACKGROUND OF THE INVENTION

1. Field of the Invention

The invention relates to methods and apparatus for treating surfaces of articles, such as semiconductor wafers, using mixtures of inorganic acid and oxidizing gas.

2. Description of Related Art

Semiconductor wafers undergo a variety of wet processing stages during manufacture of integrated circuits, one of which is removal of photoresist from the wafer. When the photoresist is stripped by a wet process, among the chemical compositions used for that stripping is a solution of sulfuric acid mixed with hydrogen peroxide (SPM). SPM processes requires addition of H₂O₂ during the treatment to replenish used-up oxidizing agent, which adds water that dilutes the acid/peroxide mixture and thus reduces its reactivity.

SOM (sulfuric acid ozone mixture) processes have also been proposed. These processes involve dissolving ozone in sulfuric acid so that the ozone reacts with the sulfuric acid to form dipersulfuric acid or peroxydisulfuric acid (H₂S₂O₈), although in aqueous acid solutions the reaction also generates water, as shown by the following equation:

2HSO₄⁻+O₃ [symbol] O₂+H₂O+S₂O₈²⁻

Ozone that does not react with sulfuric acid can also dissolve as such into the sulfuric acid solution, and thus serve as an oxidizing agent for the material to be stripped.

U.S. Pat. No. 6,701,941 describes co-dispensing deionized water and ozone into a processing chamber, such that the deionized water forms a layer on a wafer to be processed and the ozone resides within the chamber apart from the layer where it is said to diffuse through the liquid layer to the wafer surface to be treated.

### SUMMARY OF THE INVENTION

The present inventors have discovered that existing techniques for stripping photoresist from a wafer are not fully satisfactory, especially when the photoresist has previously undergone relatively high rates of ion implantation, for example during doping of the wafer with for example boron or arsenic, which makes the subsequent stripping more difficult to achieve.

The inventors' efforts to address that problem have given rise to new methods and apparatus for treating surfaces of articles, such as semiconductor wafers, using mixtures of inorganic acid and oxidizing gas. According to the invention, oxidizing gas (preferably ozone combined with other gases required for generating ozone, such as oxygen, nitrogen or carbon dioxide) and (preferably heated) inorganic acid are combined shortly before the resulting treatment fluid is brought into contact with the surface of the article to be treated, with the mixing and dispensing conditions of the treatment fluid being controlled such that the fluid takes the form of a dispersion or foam composed of bubbles of the oxidizing gas dispersed in the inorganic acid.

The present inventors have discovered that such a treatment fluid unexpectedly increases the reactivity of the fluid in relation to conventional treatment liquids, including SOM processes in which ozone is dissolved in sulfuric acid.

The methods and apparatus of the invention are not limited to use on semiconductor wafers, and have application as well for treating surfaces of other materials, for example glass masters and mother panels used in manufacturing optical disks and LCD display panels, as well as for cleaning surfaces of processing chambers used during processing of the above-described substrates.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is a schematic representation of an apparatus for treating surfaces of semiconductor wafers according to an embodiment of the invention; and

FIG. 2 is a flow chart outlining several steps of a method for treating surfaces of semiconductor wafers according to an embodiment of the invention.

### DETAILED DESCRIPTION OF PREFERRED EMBODIMENTS

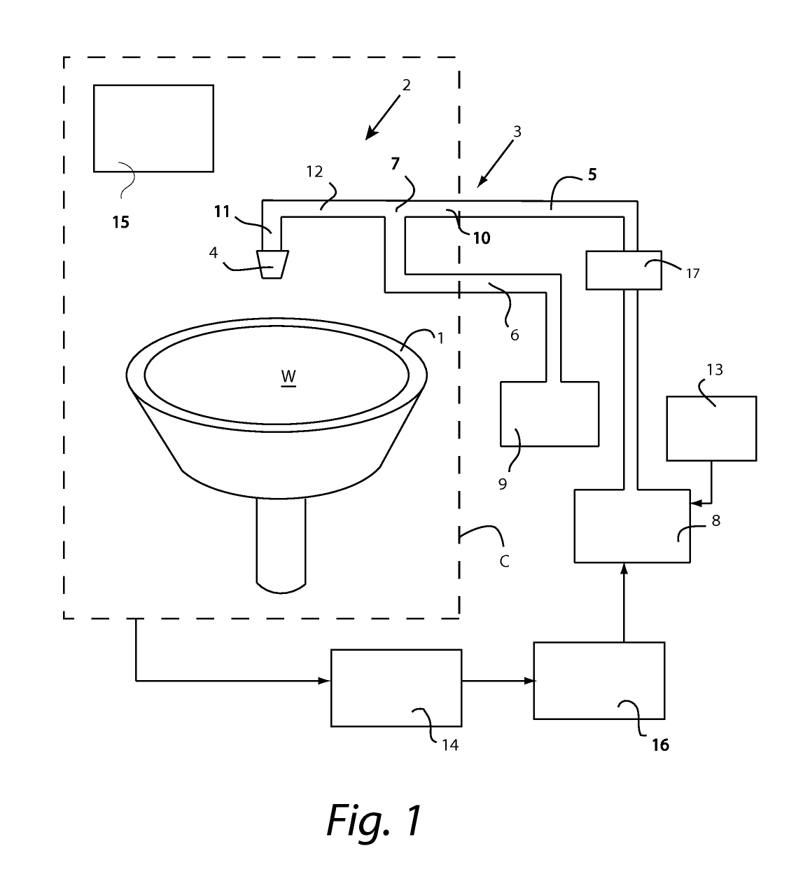

In FIG. 1 a 300 mm diameter semiconductor wafer is held by a spin chuck 1, in a surrounding processing chamber C for single wafer wet processing. Such spin chucks are described for example in commonly-owned U.S. Pat. No. 4,903,717, the entirety of which is hereby expressly incorporated by reference. As noted above, photoresist is more resistant to stripping by wet process when it has been doped during a preceding stage of ion implantation for example with boron or arsenic, which can be the case when the wet process stripping is performed during FEOL (front end of line) manufacturing of semiconductor devices.

In this embodiment, a dispenser 2 of treatment fluid comprises a dispense arm 3 with a dispense nozzle 4 configured to dispense the treatment fluid onto the wafer in a free flow. The nozzle orifice has a cross-sectional area in the range of 3 to 300 mm², and preferably 10 to 100 mm².

The treatment fluid is created by combining infeeds of heated inorganic acid, preferably sulphuric acid, and an oxidizing gas, preferably gaseous ozone, from respective feed lines 5 and 6, at a mixing junction 7. The inorganic acid is fed from a liquid supply 8 that is adapted to supply liquid to the mixing station at a flow-rate in a range of 0.5 l/min to 5 l/min, and the oxidizing gas is fed from a gas supply 9 adapted to supply gas to the mixing station at a flow-rate in a range of 0.2 l/min to 2 l/min.

The location of the mixing junction 7 where the oxidizing gas and inorganic acid are combined is preferably not more than 2 m in measured pipe length, and more preferably not more than 1 m, from the discharge orifice of the dispense nozzle 4. In this embodiment, the conduit 10 carrying inorganic acid to the mixing junction and a downstream section 11 of the conduit leading from the mixing junction 7 to the dispense nozzle 4 are each of a greater diameter than an upstream section 12 of the conduit leading from the mixing junction 7 to the dispense nozzle 4. As a particular example the diameter of conduit 10 and downstream section 11 is ⅜″ whereas the diameter of upstream section 12 is ¼″.

Mixing junction 7 preferably has the form of a T-joint where feed lines 5 and 6 meet at approximately a right angle. Alternatively, feed line 6 can penetrate into feed line 5 and become aligned with feed line 5 so as to discharge ozone gas into the inorganic acid coaxially at the mixing junction 7. This latter alternative would permit the liquid and gas to combine while travelling in a common direction, and thus with generation of less turbulence at the mixing junction 7. Depending upon the other selected process parameters and component dimensions, turbulent mixing at the mixing junction 7 may or may not be desirable.

The apparatus of this embodiment also includes a heater 13 for heating the inorganic acid before it is mixed with the oxidizing gas. In this embodiment the inorganic acid is sulphuric acid, and the heater 13 heats the acid to a temperature in a range of 100° C. to 220° C., preferably 110° C. to 180° C. As ozone becomes less soluble in sulphuric acid with increasing temperature, heating the acid to within these temperature ranges does not promote dissolution of ozone gas into the sulphuric acid.

The reference herein to inorganic acids and sulphuric acid is intended to encompass aqueous solutions of such acids, although it is preferred that such solutions are nevertheless relatively concentrated, namely, an initial concentration of at least 80 mass % and preferably of at least 90 mass %. In the case of sulphuric acid, use can be made of concentrated sulphuric acid, having a mass percent of 98.3%.

The apparatus of this embodiment also includes a fluid collector 14 as is known in the art, wherein the fluid can be collected after being spun off a rotating wafer, and a gas separator 15 wherein the excess gas is exhausted, as well as a recycling system 16 wherein the remaining liquid is returned to a process tank, from which it can be supplied to the mixing junction 7 where the gas/liquid mixture is prepared.

A flow controller 17 includes a flow meter for measuring the flow in the liquid line before the gas is added, and can adjust the rate of flow to a desired value.

Appropriate selection of the various parameters described herein permits mixing the inorganic acid and the oxidizing gas at mixing junction 7 to form a gas/liquid mixture, which constitutes the treatment fluid, so that the fluid is a mixture of the liquid as the continuous phase and the gas as the disperse phase. In particular, the dispersed phase constitutes at least 10 vol. % (preferably at least 20 vol. %) of the dispensed fluid. Most preferably, the dispersed gaseous phase constitutes from 30-50 vol. % of the treatment fluid, although the ratio of gas to liquid in the gas/liquid mixture (e.g. as vol. % of the gas) can range from 20-90 vol. %.

Heater 13 heats the inorganic acid before it is mixed with oxidizing gas to a temperature TL in a range of 100° C. to 220° C. (preferably a range of 110° C. to 180° C.). The temperature of the gas/liquid mixture when supplied to a wafer surface is about 1-5 K lower than the mixing temperature. The temperature of the inorganic acid as it reaches the mixing junction 7 is in the range of 100° C.-220° C. preferably 150°-180° C.

Dispense nozzle 4 in this embodiment preferably has a cross-sectional area of approximately ¼″ and may be formed of plural ⅛″ tubes joined to a single tube.

The wafer W is preferably rotating as the treatment fluid is dispensed onto it, and the rotational speed of the wafer is in the range of 0-1000 rpm, preferably 30-300 rpm, preferably at a speed varying over time. The inorganic acid is supplied at a volumetric flow in the range of 0.5 to 2 liter per minute (lpm), and the oxidizing gas is supplied at a volumetric flow rate of 0.1-2 lpm. Downstream of the mixing junction 7, the volumetric flow rate of the treatment fluid is preferably in the range of 0.7-5 lpm.

The concentration of the inorganic acid preferably ranges from about 80 to about 98 mass %, which in the case of sulphuric acid includes concentrated sulphuric acid at about 98.3% purity. More preferably, the concentration of the inorganic acid is at least 90 mass %.

Oxidizing gas supply 9 is preferably an ozone generator. In this regard, and as is known to those skilled in the art, ozone (O₃) is ordinarily not provided as a pure gas but rather is produced by reacting pure oxygen for example by silent electrostatic discharge, such that the generated ozone comprises oxygen (O₂) at a mass % of about 80 to about 98% and ozone in a range of about 1-20 mass %. Reference herein to ozone gas includes such ozone-enriched oxygen gases.

The temperature of the ozone-enriched oxygen gas as it approaches the mixing junction 7 may be room temperature, for example about 20° to about 25° C., however preheating of the gas to the acid temperature at the time of mixing to a temperature of up to about 50° C. is preferred.

Dispense arm 3 may be configured to operate as a boom swing, and thus move horizontally relative to and across the rotating wafer. The speed and range of the boom swing movement is sufficiently wide and fast as to promote an even temperature distribution of the treatment fluid across the wafer surface, thereby to improve uniformity of treatment over a wafer surface.

A relatively short distance and/or time between mixing of the inorganic acid with the oxidizing gas and contacting the resultant treatment fluid with the wafer surface is important to ensure that the treatment fluid retains its foam/dispersion character as it flows across the wafer surface and for the time that it resides on the wafer surface.

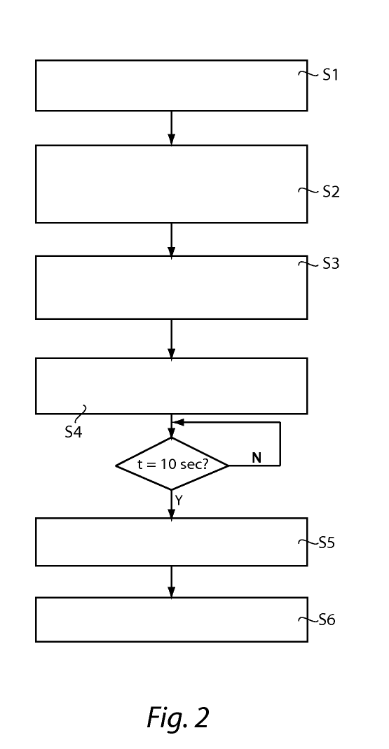

In FIG. 2, a wafer first undergoes optional pretreatment in Step S1 such as wetting to promote the contact and flow properties of the treatment fluid on the wafer surface. Next, the inorganic acid and oxidizing gas are supplied to their respective feed lines and combined at the mixing junction 7 in Step S2. The treatment fluid thus created is dispensed onto the wafer surface in Step S3. The wafer W may be rotated at the rpm described above during any or all of Steps S1, S2 and S3.

The fluid is preferably dispensed onto the wafer surface in a flow at a velocity in a range of 0.1 m/s to 10 m/s (preferably 0.3 to 3 m/s) from a nozzle orifice (or a plurality of nozzle orifices) with a cross-sectional area in the range of 3 to 300 mm², and more preferably 10 to 100 mm². These linear velocities are a function of not only flow rate through the dispense nozzle 4 but also of relative movement between the nozzle 4 and wafer W.

As discussed above, the fluid is a mixture of an inorganic acid as the continuous phase and a gas as the disperse phase (gas/liquid mixture) wherein the gas is an oxidizing gas. Suitable oxidizing gases include O₂, N₂O, NO₂, NO and mixtures thereof. The preferred oxidizing gases contain ozone at a concentration of at least 100 ppm, and the most preferred oxidizing gases are O₂/O₃ mixtures containing ozone in a range of about 1-20 mass %, balance oxygen and unintentional impurities.

The liquid and the gas are preferably mixed with each other not more than 2 seconds before the resulting treatment fluid is dispensed out of the nozzle, and more preferably not more than one second before such dispensing.

The fluid is preferably dispensed onto the wafer surface in a free flow, with the acid temperature prior to mixing being 100° C. to 220° C., preferably 110° C. to 180° C., and more preferably 150°-180° C., whereas the gas temperature prior to mixing is preferably 10-50° C.

When using H₂SO₄, the dwell time of the treatment fluid on a 300 mm diameter semiconductor wafer is preferably about 30-240 sec, with a total treatment time (i.e., including any prewet and rinse steps) of about 90-420 sec.

At the conclusion of this process stage, the liquid acid supply is preferably stopped in Step S4 before the gas supply is stopped in Step S5 (preferably at least 5 s before and more preferably at least 10 s before).

As described above, during and following treatment the fluid is collected, the excess gas is exhausted and the remaining liquid is returned to a process tank 8, from which it is supplied to the mixing junction 7 where the gas/liquid mixture is generated.

As the liquid part of the treatment fluid is recovered and recycled, the acid strength will gradually decline after a number of treatment cycles. The acid strength may be restored by addition of fresh acid to the tank 8; alternatively or in addition, the oxidizing power of the treatment fluid can be increased by adding H₂O₂ to the tank 8.

By partially draining the collector 14 over successive processing cycles, it can be possible to avoid the need to empty supply tank 8. In particular, the acid supply tank 8 can be kept in continuous service when part of the recovered liquid is drained from collector 14 and part is recirculated to tank 8. After treatment of the wafer with the oxidizing fluid is complete, an optional rinse of the wafer is performed in Step S6.

In the above embodiments it is estimated that a 40 liter acid supply tank 8 will serve to process 500-1000 wafers, assuming full recirculation, although the relation between tank size and chemical lifetime is not always linear.

The following prophetic Examples are intended to set forth particularly preferred process parameters.

### Example 1

temperature of the gas/liquid mixture 150° C.
temperature of the liquid (sulphuric acid) before being introduced to the mixing junction 150° C.
cross-sectional area of orifice of the dispense nozzle 72 mm² (for ⅜″ orifice)
spin speed of the wafer 150 rpm
volume flow of liquid 1.6 l/min
volume flow of gas 0.6 l/min
volume flow of mixture 2.2 l/min
dispense speed at orifice 1 m/s
ratio of gas to liquid in the gas/liquid mixture 27 vol. %
concentration of sulphuric acid (mass %) 97-80 mass %
ozone in gas (10 mass %), balance oxygen and unintentional impurities

### Example 2

temperature of the gas/liquid mixture 153° C.
temperature of the liquid (sulphuric acid) before being introduced to the mixing junction 140° C.
cross-sectional area of orifice of the dispense nozzle 30 mm² (for ¼″ orifice)
spin speed of the wafer 100 rpm
volume flow of liquid 0.6 l/min
volume flow of gas 1.6 l/min
volume flow of mixture 2.2 l/min
dispense speed at orifice 1 m/s
ratio of gas to liquid in the gas/liquid mixture (e.g. as vol. % of the gas) 70 vol. %
concentration of sulphuric acid (mass %) 96-88 mass %
ozone in gas (12 mass %), balance oxygen and unintentional impurities

While the present invention has been described in connection with various preferred embodiments thereof, it is to be understood that those embodiments are provided merely to illustrate the invention, and should not be used as a pretext to limit the scope of protection conferred by the true scope and spirit of the appended claims.

What is claimed is:

1. A method for treating a surface of an article with an oxidizing fluid, comprising dispensing an oxidizing fluid onto a surface of an article to be treated, wherein said oxidizing fluid is a mixture of an inorganic acid and an oxidizing gas, said oxidizing fluid having the form of a dispersed phase of bubbles of said oxidizing gas in a continuous phase of said inorganic acid, wherein the dispersed phase constitutes at least 10 vol. % of said oxidizing fluid.

2. The method according to claim 1, wherein said article is a semiconductor wafer, and wherein said surface to be treated comprises photoresist that includes ions implanted during a previous processing stage.

3. The method according to claim 2, wherein the semiconductor wafer is positioned on a spin chuck in a single wafer wet processing station.

4. The method according to claim 1, wherein the fluid is dispensed onto the surface in a flow at a velocity in a range of 0.1 m/s to 10 m/s from at least one nozzle orifice with a cross-sectional area in the range of 3 to 300 mm².

5. The method according to claim 1, wherein the inorganic acid is an aqueous solution of an inorganic acid at a concentration of at least 80 mass % or a pure acid.

6. The method according to claim 5, wherein the inorganic acid is an aqueous solution of sulphuric acid at a concentration of at least 90 mass % or pure sulphuric acid (oleum).

7. The method according to claim 1, wherein the oxidizing gas contains ozone at a concentration of at least 100 ppm.

8. The method according to claim 7, wherein the oxidizing gas comprises ozone at a concentration in a range of about 1-20 mass % and oxygen at a concentration in a range of about 80-98 mass %.

9. The method according to claim 1, further comprising heating the inorganic acid to a temperature TL in a range of 100° C. to 220° C. before mixing with the oxidizing gas.

10. The method according to claim 9, wherein said temperature TL is in a range of 150° C. to 180° C.

11. An apparatus for treating a surface of an article with an oxidizing fluid, comprising:
a dispenser comprising a dispense arm with a dispense nozzle for dispensing the fluid onto the wafer in a free flow, wherein the nozzle has an orifice having a cross-sectional area in the range of 3 to 300 mm²;
a mixing junction communicating with infeed conduits of inorganic acid and oxidizing gas, said mixing junction being adapted to generate said oxidizing fluid in the form of a gas/liquid dispersion and supply said oxidizing fluid via a downstream conduit to said dispense nozzle;
wherein said mixing junction is positioned not more than 2 m of conduit length from said dispense nozzle, such that the oxidizing fluid remains a gas/liquid dispersion upon exiting said orifice.

12. The apparatus according to claim 11, wherein said apparatus is a single wafer wet processing station comprising a spin chuck adapted to hold a semiconductor wafer, and said nozzle is positioned relative to said spin chuck so as to dispense said oxidizing fluid downwardly onto an upwardly facing surface of the semiconductor wafer in a free flow.

13. The apparatus according to claim 11, further comprising a heater for heating the inorganic acid upstream of said mixing junction to a temperature in a range of 100° C. to 220° C.

14. The apparatus according to claim 11, further comprising a flow controller comprising a flow meter positioned upstream of said mixing junction and adapted to measure a flow rate of the inorganic acid in an associated conduit before it is mixed with the oxidizing gas.

15. The apparatus according to claim 11, wherein said nozzle orifice, said mixing junction and said infeed conduits of inorganic acid and oxidizing gas are dimensioned and positioned relative to one another so as to produce an oxidizing fluid at said nozzle orifice having a dispersed phase of bubbles of said oxidizing gas in a continuous phase of said inorganic acid, wherein the dispersed phase constitutes at least 10 vol. % of said oxidizing fluid.
